(19) United States
(12) Patent Application Publication
(10) Pub. No.: US 2025/0120141 A1
(43) Pub. Date: Apr. 10, 2025

(54) SEMICONDUCTOR STRUCTURE AND METHOD OF MANUFACTURING THE SAME

(71) Applicant: NANYA TECHNOLOGY CORPORATION, New Taipei City (TW)

(72) Inventor: Wei-Chih WANG, Taoyuan City (TW)

(21) Appl. No.: 18/376,553

(22) Filed: Oct. 4, 2023

(51) Int. Cl. H01L 29/06; H10B 12/00

(52) U.S. Cl. CPC H10D 62/124; H10B 12/02; H10B 12/488

(57) ABSTRACT

Embodiments of this disclosure provide a semiconductor structure including a substrate. The substrate includes active areas and insulation areas between the active areas. A first end of each of the active areas has a first head portion, a second end of each of the active areas has the second head portion, and a middle portion of each of active areas has a waist portion. In a top view, the first head portion and the second head portion of each of the active areas have a first width, respectively, and the waist portion of each of the active areas has a second width. Also, the first width is greater than the second width. Moreover, a method of manufacturing a semiconductor structure also is provided herein.

### BACKGROUND

### Field of Invention

The present disclosure relates to a semiconductor structure and a method of manufacturing the same. More particularly, the present disclosure relates to a semiconductor structure and a method of manufacturing the same including an active area with a hammer-head shape.

### Description of Related Art

As electronic devices become lighter and thinner, semiconductor devices, such as dynamic random access memory (DRAM) become more highly integrated. Further, the performance of the DRAM is improved via shortening the pitch between the semiconductor structures in the DRAM. Due to shrinking the size of the semiconductor structure, in addition to increasing the difficulty of the manufacturing process, the components in the semiconductor structures are also prone to leakage resulting from too close distances.

As a result, in the semiconductor manufacturing process, how to reduce the leakage to improve the process yield of the semiconductor structure has become an important issue.

### SUMMARY

Embodiments of this disclosure provide a semiconductor structure. The semiconductor structure includes a substrate including active areas and insulation areas between the active areas. The substrate includes active areas and insulation areas between the active areas. A first end of each of the active areas has a first head portion, a second end of each of the active areas has the second head portion, and a middle portion of each of active areas has a waist portion. In a top view, the first head portion and the second head portion of each of the active areas have a first width, respectively, and the waist portion of each of the active areas has a second width. Also, the first width is greater than the second width.

In some embodiments, a difference percentage between the first width and the second width is 20% to 30%.

In some embodiments, a maximum ratio of the first width to the second width is 10:8.

In some embodiments, a minimum ratio of the first width to the second width is 10:7.

In some embodiments, the first width is 20 nm, and the second width is 14 to 16 nm.

In some embodiments, the semiconductor structure further includes source/drain regions. Each of the source/drain regions is disposed in each of the active areas and between the insulation areas.

In some embodiments, the semiconductor structure further includes word line structures. Each of the word line structures extends through the insulation areas and the active areas.

In some embodiments, each of the active areas is equipped with 3 to 4 word line structures on average.

In some embodiments, one of the source/drain regions collectively shares the adjacent word line structures and is controlled by the adjacent word line structures.

Embodiments of this disclosure provide a method of manufacturing a semiconductor structure. The method includes the following steps. A substrate is provided. Insulation areas in the substrate to define a plurality of active areas are formed. Two ends of head portions of each of the active areas on a top surface of the substrate has a first width, respectively. A middle portion of each of the active areas on the top surface of the substrate has a second width. Besides, the first width is greater than the second width. Moreover, word line structures on the top surface of the substrate are formed.

In some embodiments, forming the plurality of insulation areas in the substrate includes the following steps. A mask is formed on the top surface of the substrate. Portions not covered by the hard mask are exposed. The exposed portions are etched to form openings. A first dielectric layer is deposited in the openings and over the substrate.

In some embodiments, after forming the plurality of insulation areas and the plurality of active areas, a top surface of the plurality of insulation areas and a top surface of the plurality of active areas are coplanar.

In some embodiments, the method further includes the following steps. Source/drain regions are formed in the active areas.

In some embodiments, one of the source/drain regions collectively shares the adjacent word line structures and is controlled by the adjacent word line structures.

In some embodiments, forming the plurality of word line structures includes the following steps. First trenches with a first depth are formed in the active area and the insulation areas. A conductive layer is deposited in each of the first trenches. A cap layer is deposited in each of the first trenches and on the conductive layer.

In some embodiments, forming the plurality of word line structures includes the following steps. A dielectric liner is deposited in each of the first trenches prior to depositing the conductive layer.

In some embodiments, the dielectric liner surrounds the conductive layer and the cap layer, but the dielectric liner does not cover a top surface of the cap layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. The disclosure can be more fully understood by reading the following detailed description of the embodiment, with reference made to the accompanying drawings as follows.

FIGS. 1-5 are views of a method of manufacturing a semiconductor structure during forming the active areas with hammer-head shape according some embodiments of the present disclosure,

FIGS. 6-10 are views of a method of manufacturing a semiconductor structure during forming a plurality of word line structures according some embodiments of the present disclosure, and

FIG. 11 is a schematic diagram of a semiconductor structure according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The words “comprise,” “include,” “have,” “contain” and the like used in the present disclosure are open terms, meaning including but not limited to.

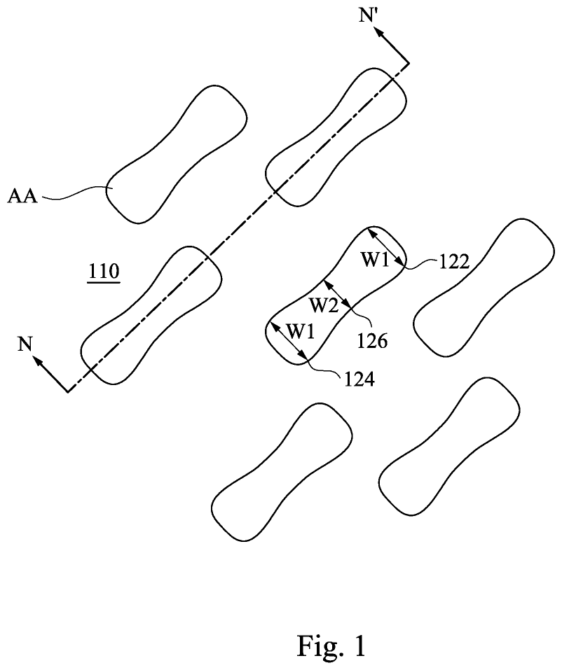

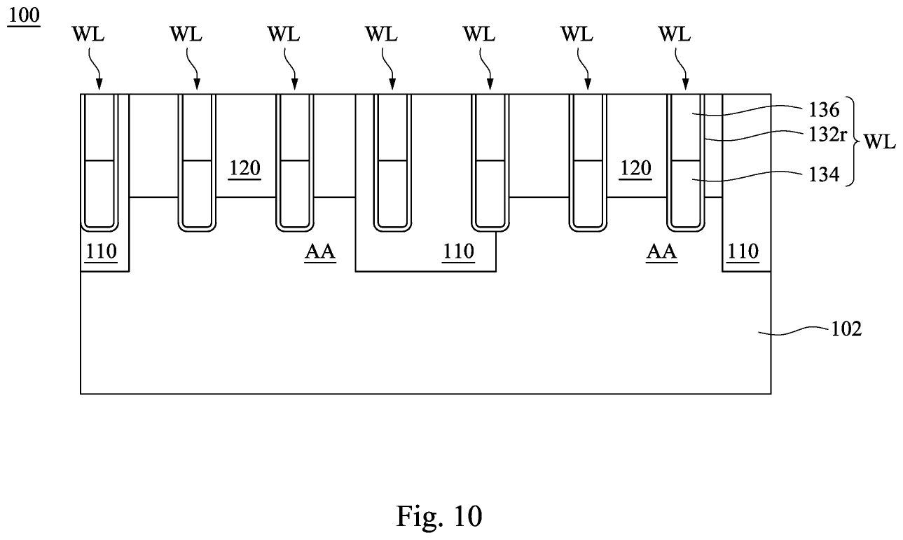

It should be noted that when the following figures, such as FIGS. 1 to 10, are illustrated and described as a series of operations or steps, the description order of these operations or steps should not be limited. For example, some operations or steps may be undertaken in a different order than in the present disclosure, or some operations or steps may occur currently, or some operations may not be used, and/or some operations or steps may be repeated. Moreover, the actual operations or steps of process stages may require additional operations or steps before, during or after forming the semiconductor structure (for example, a semiconductor structure 100 in FIG. 10) to completely form the semiconductor structure 100. Therefore, the present disclosure may briefly illustrate some of these additional operations or steps. Further, unless otherwise stated, the same explanations discussed for the following figures, such as FIGS. 1 to 10, apply directly to the other figures.

In related art, an array semiconductor structure, which means the arrangement of the active areas in a semiconductor structure with a top view is an array, formed by the long and narrow active areas leads to the problem that the resistance value of cell side contact of each of the active areas, such as two ends of each of the active areas, of the semiconductor structure is too large. Even, due to decreasing of the size of the semiconductor structure, the resistance value of each of the active areas increases significantly. Therefore, embodiments of the present disclosure increase the size of the cell side of each of the active areas (e.g. two ends of each of the active areas) and decrease the size of the digital side of each of the active areas (e.g. a middle portion of each of the active areas) to reduce the resistance value and improve the current of each of source/drain regions. That is, the embodiments of the present disclosure reduce the resistance and improve the current of each of source/drain regions by changing the long and narrow active area into an active area with a hammer-head shape.

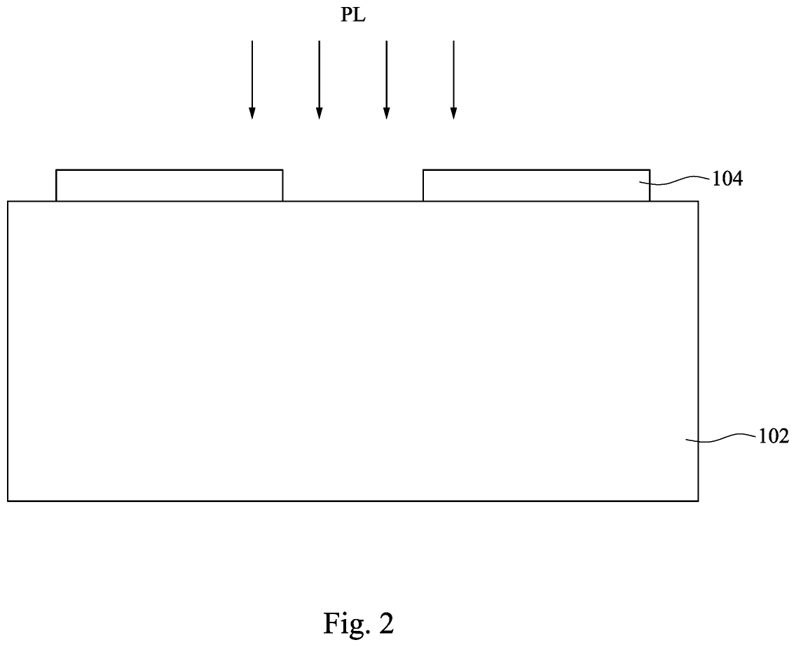

The embodiments of the present disclosure also provide a method of manufacturing the semiconductor structure 100 with a plurality of active areas AA with the hammer-head shape to reduce the resistance and improve the current of each of source/drain regions. First, please refer to FIGS. 1-5. FIGS. 1-5 are views of a method of manufacturing a semiconductor structure 100 during forming the active areas AA with hammer-head shape according some embodiments of the present disclosure, wherein FIG. 1 is a top view of a semiconductor structure 100 with the active areas AA with the hammer-head shape and a plurality of insulation areas 110 according some embodiments of the present disclosure, and FIGS. 2-5 are cross-sectional views taken along a section-line NN′ of FIG. 1 during one of forming the active areas AA with the hammer-head shape according some embodiments of the present disclosure, respectively.

As shown in FIG. 2, a substrate 102 is provided. In some embodiments, the substrate 102 may include silicon, such as crystalline silicon, polycrystalline silicon, or amorphous silicon. The substrate 102 may include an elemental semiconductor, such as germanium. In some embodiments, the substrate 102 may include alloy semiconductors, such as silicon germanium, silicon germanium carbide, gallium indium phosphide, or other suitable materials. In some embodiments, the substrate 102 may include compound semiconductors, such as silicon carbide (SiC), gallium arsenide (GaAs), indium phosphide (InP), indium arsenide (InAs), or other suitable materials. Besides, in some embodiments, the substrate 102 can optionally have a semiconductor-on-insulator (SOI) structure.

In order to form the active areas AA (as shown in FIG. 1) and the insulation areas 110 (as shown in FIG. 1) in the substrate 102, a mask 104 is formed on the top surface of the substrate 102. After forming the mask 104, the portions that expected to be the active areas AA (as shown in FIG. 1) are covered, and other portions that expected to be the insulation areas 110 (as shown in FIG. 1) are exposed. Then, the exposed portions are exposed by a photolithography process PL. In some embodiments, the mask 104 is a hard mask. In some embodiment, a material of the mask 104 is silicon nitride.

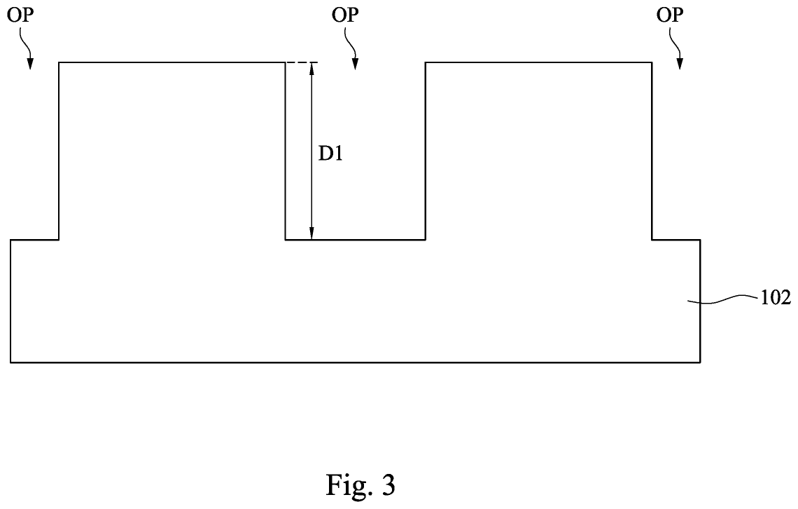

Next, please refer to FIG. 3. An etching process is performed to remove upper portions of the exposed portions of the substrate 102, so as to form a plurality of openings OP. Also, each of the openings OP has a first depth D1. In some embodiments, the etching process for removing upper portions of the exposed portions of the substrate 102 is a dry etching process, a wet etching process or any suitable etching process. Then, the mask 104 (as shown in FIG. 2) is removed by a planarization process. In some embodiments, the planarization process is a chemical mechanism polish (CMP) process, an etching process or a combination thereof. It should be noted that although the number of the openings OP illustrated in FIG. 3 is 3, the present disclosure is not limited thereto.

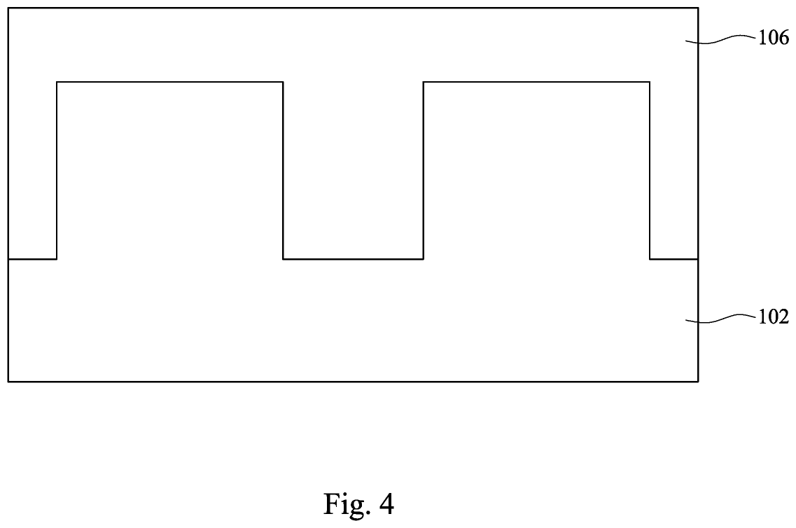

Further, please refer to FIG. 4. A first dielectric layer 106 is deposited in the openings OP (as shown in FIG. 3) and over the substrate 102. In some embodiments, the first dielectric layer 106 is formed of any suitable dielectric material. In some embodiments, the dielectric material may include an oxide, such as silicon oxide. In some embodiments, the formation method of the first dielectric layer 106 includes using an atomic layer deposition process, other suitable techniques or a combination thereof.

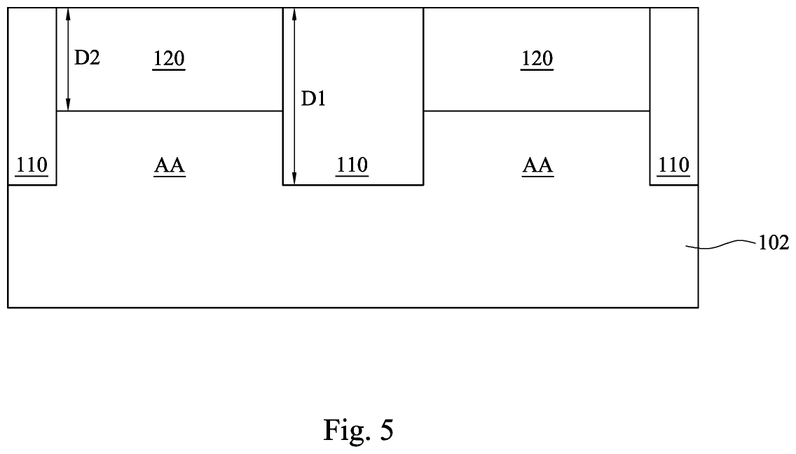

Then, as shown in FIG. 5, a plurality of source/drain (S/D) regions 120 are formed in the active areas AA of the substrate 102. More specifically, the excess first dielectric layer 106 is removed by a planarization process after depositing the first dielectric layer 106 in the openings OP (as shown in FIG. 3) and over the substrate 102. In some embodiments, the planarization process is a CMP process, an etching process or a combination thereof. After planarization process, the active areas AA and the insulation areas 110 are formed. Also, the top surface of the active areas AA and the top surface of the insulation areas 110 are coplanar (within process variation). Although the number of the active areas AA and the insulation areas 110 illustrated in FIG. 5 is 2 and 3, respectively, the present disclosure is not limited thereto.

Further, please return to FIG. 1. After forming the active areas AA, the technical features of the active areas AA with the hammer-head shape are described below. A first end of each of the active areas AA has a first head portion 122, and the first head portion 122 is referred to the widest portion of the first end of each of the active areas AA. A second end of each of the active areas AA has a second head portion 124. As well, the second head portion 124 is referred to as the widest portion of the second end of each of the active areas AA. A middle portion of each of the active areas AA has a waist portion 126. The waist portion 126 is referred to as the narrowest portion of the middle portion of each of the active areas AA. The first head portion 122 and the second head portion 124 of each of the active areas AA have a first width W1, respectively. The waist portion 126 of each of the active areas AA has a second width W2. Moreover, the first width W1 is greater than the second width W2. In some embodiments, a difference percentage between the first width W1 and the second width W2 is 20% to 30%. In some embodiments, a maximum ratio of the first width W1 to the second width W2 is 10:8. In some embodiments, wherein a minimum ratio of the first width W1 to the second width W2 is 10:7. For example, when the first width W1 is 20 nm, and the second width W1 is 14 to 16 nm, but the present disclosure is not limited thereto. It should be noted that when the second width W2 is less than 14 nm, there are difficulties for manufacturing the active areas AA, and it also affects the subsequent manufacturing processes of word line structures, bit line structures and so on. When the second width W2 is greater than 16 nm, the effects of reducing the resistance and improving the current of each of source/drain regions cannot be achieved.

Then, please refer to FIG. 5. To form the S/D regions 120, an ion implantation process may be performed on the substrate 102 to dope N-type or P-type dopants into the active areas AA of the substrate 102. In some embodiments, the N-type dopants may include phosphorus or arsenic, and the P-type dopants include boron or boron fluoride. In addition, each the S/D regions 120 has a second depth D2. Also, the second depth D2 of the S/D regions 120 is less than the first depth D1 of each of the insulation areas 110.

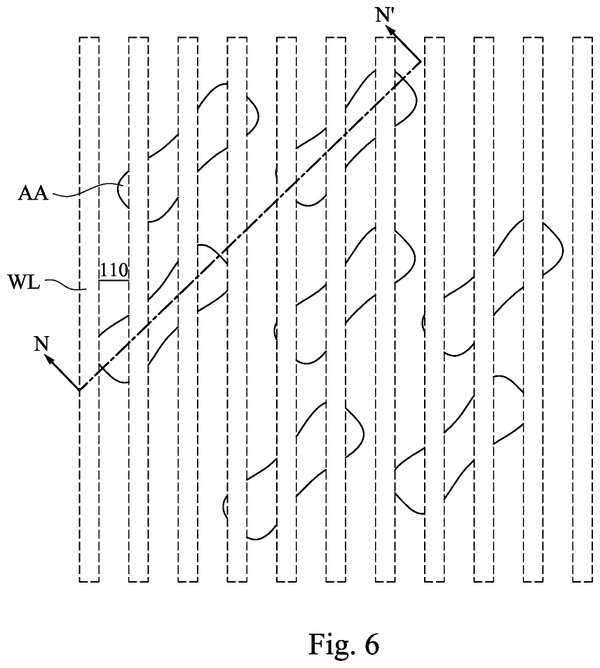

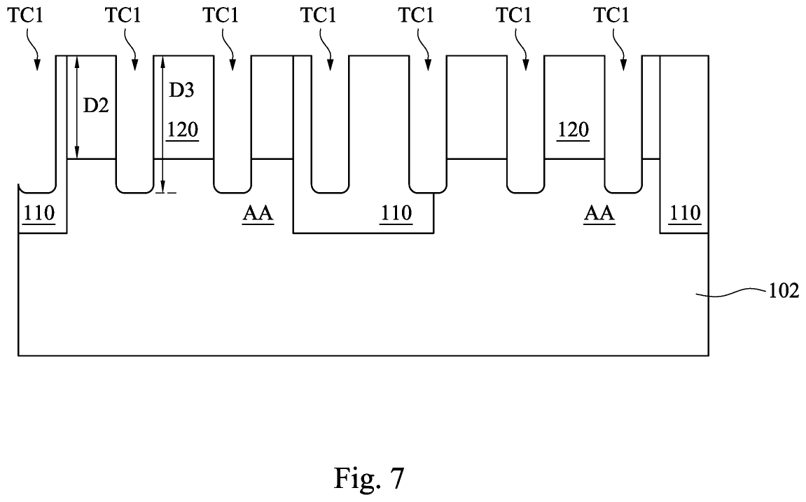

Please refer to FIGS. 6-10. FIGS. 6-10 are views of a method of manufacturing a semiconductor structure 100 during forming a plurality of word line structures WL according some embodiments of the present disclosure, wherein FIG. 6 is a top view of a semiconductor structure 100 with the word line structures WL according some embodiments of the present disclosure, and FIGS. 7-10 are cross-sectional views taken along a section-line NN′ of FIG. 6 during one of forming the word line structures WL according some embodiments of the present disclosure, respectively.

As shown in FIGS. 6 and 7, a plurality of first trenches TC1 for word line structures (e.g. the word line structures WL in FIG. 10) are formed in the substrate 102. More specifically, the first trenches TC1 are formed by a photolithography process and an etching process. Similar to that shown in FIG. 6, the first trenches TC1 extend through the insulation areas 110 and the active areas AA. Further, the distribution of the first trenches TC1 expected to be the word line structures WL is fairly dense in the top view. For example, but not limited to, there are 3 to 4 first trenches TC1 distributed between each of the active areas AA.

Next, as shown in FIG. 7, an etching depth of each of the first trenches TC1 is a third depth D3. The third depth D3 is greater than the second depth D2 of each of the S/D regions 120. Also, although the number of the first trenches is 7 in FIG. 7, the present disclosure is not limited thereto.

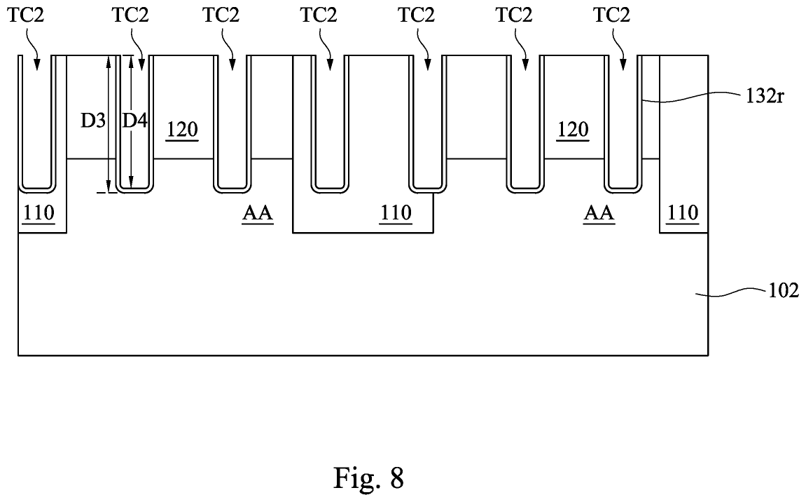

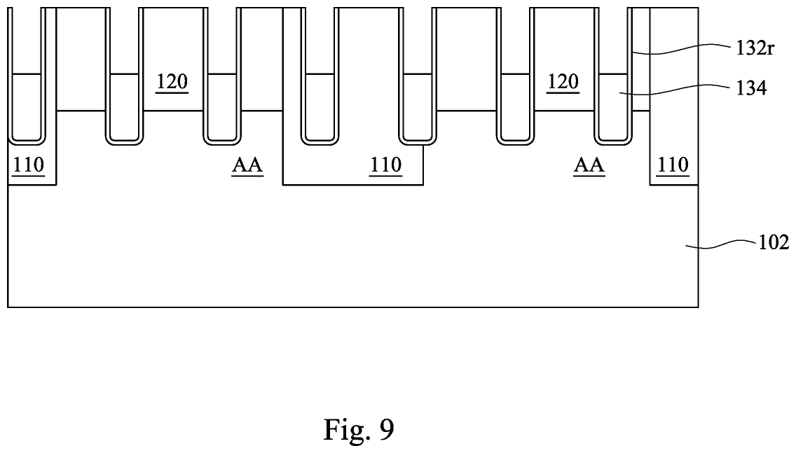

Further, as shown in FIG. 8, a plurality of second trenches TC2 are formed in the first trenches TC1. As well, in the top view, the second trenches TC2 extend through the insulation areas 110 and the active areas AA. More specifically, a thin layer of a dielectric liner 132r is deposited in the first trenches TC1 (as shown in FIG. 7). The fourth depth D4 is less than the third depth D3 of each of the first trenches TC1. In some embodiments, the dielectric liner 132r is formed by an atomic layer deposition process, other suitable techniques or a combination thereof. Also, although the number of the second trenches TC2 is 7 in FIG. 9, but the present disclosure is not limited thereto.

Then, as shown in FIG. 9, a conductive layer 134 is deposited in each of the second trenches TC2. More specifically, the conductive layer 134 is formed within each of the second trenches TC2 and contacts the bottom portion of dielectric liner 132r and the side portion of dielectric liner 132r. The location of the conductive layer 134 at least partially overlaps with each of the S/D regions 120, that is, the S/D regions 120 are disposed on opposite sides of the conductive layer 134. In some embodiments, the conductive layer 134 is formed of any suitable conductive material, such as semiconductor, metal, metal nitride, metal silicide, other suitable conductive materials or a combination thereof. For example, the conductive layer 134 may include doped polysilicon, titanium (Ti), tungsten (W), tantalum (Ta), titanium nitride (TiN), tungsten nitride (WN), tantalum nitride (TaN), Titanium silicon nitride (TiSiN), tantalum silicon nitride (TaSiN), tungsten silicon nitride (WSiN), other suitable conductive materials or a combination thereof.

Next, as shown in FIG. 10, a cap layer 136 is formed within each of the second trenches TC2 and on the conductive layer 134. In some embodiments, the material of the cap layer 136 may include silicon oxide, silicon nitride, silicon oxynitride or a combination thereof. Moreover, after forming the cap layer 136, a planarization process is performed. In some embodiments, the planarization process is a CMP process, an etching process or a combination thereof.

After the steps in FIG. 10, the semiconductor structure 100 including the active areas AA with hammer-head shape areas has been completed. As shown in FIG. 10, due to an area of each of the active areas AA increasing, the number of the word line structures WL covering each of the active areas AA is also increased. In this way, the distribution of the word line structure WL is fairly dense in the top view. For example, but not limited to, each of the active areas is equipped with 3 to 4 word line structures on average. Thus, one S/D region 120 can collectively share the adjacent word line structures WL and be controlled by the adjacent word line structures WL. Although the number of the word line structures WL is 7 in FIG. 10, the present disclosure is not limited thereto.

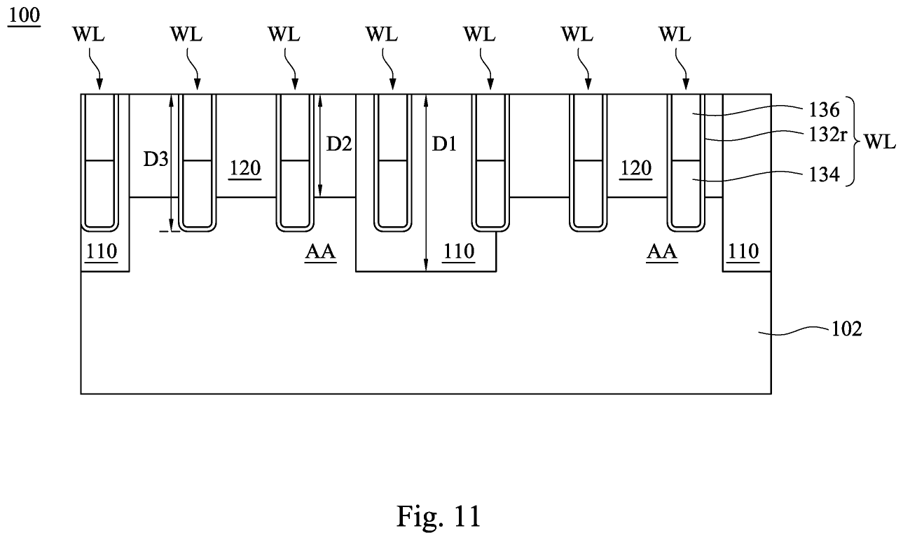

Furthermore, the embodiments of the present disclosure also provide a semiconductor structure 100 including the active areas AA with the hammer-head shape. Please refer to FIG. 11. FIG. 11 is a schematic diagram of a semiconductor structure 100 according to some embodiments of the present disclosure.

The semiconductor structure 100 includes a substrate 102 including the active areas AA and the insulation areas 110. The active areas AA are defined by the plurality of insulation areas 110. Further, the insulation areas 110 are between the active areas AA. Each of the insulation areas 110 has the first depth D1.

As shown in FIG. 6, a first end of each of the active areas has the first head portion 122. The first head portion 122 is referred to the widest portion of the first end of each of the active areas AA. A second end of each of the active areas AA has a second head portion 124. As well, the second head portion 124 is referred to as the widest portion of the second end of each of the active areas AA. A middle portion of each of the active areas AA has a waist portion 126. The waist portion 126 is referred to as the narrowest portion of the middle portion of the active areas AA. The first head portion 122 and the second head portion 124 of each of the active areas have a first width W1, respectively. The waist portion 126 of each of the active areas AA has a second width W2. Moreover, the first width W1 is greater than the second width W2. In some embodiments, a difference percentage between the first width W1 and the second width W2 is 20% to 30%. In some embodiments, a maximum ratio of the first width W1 to the second width W2 is 10:8. In some embodiments, wherein a minimum ratio of the first width W1 to the second width W2 is 10:7. For example, when the first width W1 is 20 nm, and the second width W1 is 14 to 16 nm, but the present disclosure is not limited thereto. It should be noted that when the second width W2 is less than 14 nm, there are difficulties for manufacturing the active areas AA, and it also affects the subsequent manufacturing processes of word line structures, bit line structures and so on. When the second width W2 is greater than 16 nm, the effects of reducing the resistance and improving the current of each of source/drain regions cannot be achieved.

In addition, the semiconductor structure 100 further includes the S/D regions 120. Each of the S/D regions 120 is disposed in the active area AA and between the insulation areas 110. Each of the S/D regions 120 has a second depth D2, and the second depth D2 is less than the first depth D1.

As shown in FIG. 11, the semiconductor structure 100 further includes the word line structures WL. In the top view (e.g. FIG. 6), each of the word line structures WL is linear and extends through the insulation areas 110 and active areas AA. Further, each of the word line structures WL includes a conductive layer and a cap layer. The conductive layer is referred to as the lower portion of each of the word line structures. In some embodiments, the conductive layer 134 is formed of any suitable conductive material, such as semiconductor, metal, metal nitride, metal silicide, other suitable conductive materials or a combination thereof. For example, the conductive layer 134 may include doped polysilicon, titanium (Ti), tungsten (W), tantalum (Ta), titanium nitride (TiN), tungsten nitride (WN), tantalum nitride (TaN), Titanium silicon nitride (TiSiN), tantalum silicon nitride (TaSiN), tungsten silicon nitride (WSiN), other suitable conductive materials or a combination thereof. The cap layer is referred to as the upper portion of each of the word line structures, and the cap layer is disposed on the conductive layer. In some embodiments, the material of the cap layer 136 may include silicon oxide, silicon nitride, silicon oxynitride or a combination thereof.

Furthermore, the location of the conductive layer 134 at least partially overlaps with each of the S/D regions 120. That is, the S/D regions 120 are disposed on opposite sides of the conductive layer 134. Since the word line structures WL of the embodiments of the present disclosure are fairly dense, the one S/D region 120 can collectively share the adjacent word line structures WL and be controlled by the adjacent word line structures WL. Although the number of the word line structures WL is 7 in FIG. 11, the present disclosure is not limited thereto.

In addition, each of the word line structures WL includes a dielectric liner 132r. The dielectric liner 132r is disposed surrounding the conductive layer 134 and the cap layer 136. That is, the conductive layer 134 contacts the bottom portion of the dielectric liner 132r and the side portion of the dielectric liner 132r. Also, the cap layer 136 contacts the upper portion of the dielectric liner 132r. Moreover, each of the word line structures WL has the third depth D3. The third depth D3 is less than the second depth D2, as well the third depth D3 is less than the first depth D1.

Via the method of manufacturing the semiconductor structure 100 and the semiconductor structure 100 of the embodiments of the present disclosure, the active areas AA with the hammer-head shape can be obtained. Two ends of each of the active areas AA are wider than the middle portion of each of the active areas AA. In this way, the resistance of the cell side contact of each of the active areas AA can be reduced effectively. Also, although narrowing the middle portion of the active areas AA (digital side) may sacrifice a little linear current of each of the S/D regions 120, the maximum current of each of the S/D regions can be significantly increased. Consequently, the embodiments of the present disclosure can reduce the contact resistance to improve the performance of the current of S/D regions in the array semiconductor structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor structure, comprising:
a substrate, comprising a plurality of active areas and a plurality of insulation areas between the plurality of active areas,
wherein a first end of each of the plurality of active areas has a first head portion, a second end of each of the plurality of active areas has a second head portion, and a middle portion of each of the plurality of active areas has a waist portion,
wherein in a top view, the first head portion and the second head portion of each of the plurality of active areas have a first width, respectively, and the waist portion of each of the plurality of active areas has a second width, and
wherein the first width is greater than the second width.

2. The semiconductor structure of claim 1, wherein a difference percentage between the first width and the second width is 20% to 30%.

3. The semiconductor structure of claim 2, wherein a maximum ratio of the first width to the second width is 10:8.

4. The semiconductor structure of claim 2, wherein a minimum ratio of the first width to the second width is 10:7.

5. The semiconductor structure of claim 2, wherein the first width is 20 nm, and the second width is 14 to 16 nm.

6. The semiconductor structure of claim 1, further comprising:
a plurality of source/drain regions, disposed in each of the plurality of active areas and between the plurality of insulation areas.

7. The semiconductor structure of claim 6, further comprising:
a plurality of word line structures, extending through the insulation areas and the active areas.

8. The semiconductor structure of claim 7, wherein each of the active areas is equipped with 3 to 4 word line structures on average.

9. The semiconductor structure of claim 8, wherein one of the source/drain regions collectively shares the adjacent word line structures and is controlled by the adjacent word line structures.

10. A method of manufacturing a semiconductor structure, comprising:
providing a substrate;
forming a plurality of insulation areas in the substrate to define a plurality of active areas, wherein two ends of head portions of each of the active areas on a top surface of the substrate has a first width, respectively, a middle portion of each of the active areas on the top surface of the substrate has a second width, and the first width is greater than the second width; and
forming a plurality of word line structures on the top surface of the substrate.

11. The method of claim 10, wherein forming the plurality of insulation areas in the substrate comprises:
forming a mask on the top surface of the substrate;
exposing portions not covered by the mask;
etching the exposed portions to form openings; and
depositing a first dielectric layer in the openings and over the substrate.

12. The method of claim 10, wherein a difference percentage between the first width and the second width is 20% to 30%.

13. The method of claim 12, wherein the first width is 20 nm, and the second width is 14 to 16 nm.

14. The method of claim 10, wherein after forming the plurality of insulation areas and the plurality of active areas, a top surface of the plurality of insulation areas and a top surface of the plurality of active areas are coplanar.

15. The method of claim 10, further comprising:
forming a plurality of source/drain regions in the active areas.

16. The method of claim 15, wherein each of the active areas is equipped with 3 to 4 word line structures on average.

17. The method of claim 16, wherein one of the source/drain regions collectively shares the adjacent word line structures and is controlled by the adjacent word line structures.

18. The method of claim 15, wherein forming the plurality of word line structures comprises:
forming a plurality of first trenches with a first depth in the active area and the insulation areas;
depositing a conductive layer in each of the plurality of first trenches; and
depositing a cap layer in each of the plurality of first trenches and on the conductive layer.

19. The method of claim 18, wherein forming the plurality of word line structures comprises:
depositing a dielectric liner in each of the plurality of first trenches prior to depositing the conductive layer.

20. The method of claim 19, wherein the dielectric liner surrounds the conductive layer and the cap layer.
